(19) United States
(12) Patent Application Publication
(10) Pub. No.: US 2007/0019371 A1
(43) Pub. Date: Jan. 25, 2007

(54) Multimedia display device attached to a sunroof of vehicles

(75) Inventor: Cheng-Chi Yang, Sihu Township (TW)

Correspondence Address: BRUCE H. TROXELL, SUITE 1404, 5205 LEESBURG PIKE, FALLS CHURCH, VA, 22041, US

(73) Assignee: E-Lead Electronic Co., Ltd.

(21) Appl. No.: 11/186,752

(22) Filed: Jul. 22, 2005

(51) Int. Cl. G06F 1/16; H05K 5/00

(52) U.S. Cl. 361/681; 361/679

(57) ABSTRACT

A multimedia display device attached to a sunroof of vehicles that can be rapidly installed on and removed from the bottom side of the sunroof to prevent pilferage and provide a better viewing position for entertainment of passengers on the rear seat includes an anchor base and a portable display device. The anchor base is bonded to the bottom surface of the sunroof and has housing recess to hold the portable display device. The anchor base further has a wedging mechanism to wedge one end of the portable display device and an anchor mechanism to anchor the portable display device. The portable display device can be flipped up and down on the anchor base, and removed from the anchor base when the passengers leave the vehicle. The multimedia display device can be installed on the sunroof to be seen by users without affecting operation of the sunroof.

### BACKGROUND OF THE INVENTION

1. Field of the Invention

The invention relates to a multimedia display device attached to a sunroof of vehicles and particularly to multimedia display device that can be rapidly installed on and removed from the bottom side of the sunroof of vehicles to prevent pilferage and provide entertainment for passengers on the rear seat.

2. Description of the Prior Art

The conventional multimedia display device for vehicles generally is installed on the dashboard on the front side. To avoid distracting the driver, the display device usually is not playing during driving. Some display devices are located on the headrest of the front seat so that passengers on the rear seat can see. Installation is quite complex. Moreover, one single display device cannot provide desired entertainment for all the passengers on the rear seat. It is also quite expensive. There are other schemes that install the display device on the car roof. R.O.C. patent publication No. 93202097 discloses a roof attached LCD screen which has a recess on a top seat with one side to hinge a suspension panel. The suspension panel can hold a LCD device, and be swiveled upwards and downwards. The top seat is fastened to the car roof. It is not easy to install. For vehicles that have a sunroof, it is difficult to find a suitable installing location

### SUMMARY OF THE INVENTION

In view of the aforesaid problems occurred to the conventional multimedia display device on the vehicles that is difficult to install and not suitable for the vehicles that have a sunroof, the present invention aims to provide a multimedia display device attached to a sunroof of vehicles to provide entertainment for passengers on the rear seat that may be rapidly installed and removed to prevent pilferage.

The invention includes an anchor base and a portable display device. The anchor base has a wedging mechanism and an anchor mechanism. The anchor base is bonded to the bottom surface of a sunroof of vehicles, and has a housing recess to hold the portable display device. The wedging mechanism is located on an inner side of the housing recess, and has a latch hook to latch a latch trough formed on one end of the portable display device. The anchor mechanism provides holding and releasing functions, and has a latch tongue engageable with an anchor trough of the display device. Hence the portable device can be held and anchored in the housing recess of the anchor base, and swiveled up and down relative to the anchor base. When not in use and the passengers leave the vehicle, the portable display device may be removed from the anchor base. By means of the aforesaid structure, the problem of installation difficulty for vehicles equipped with a sunroof can be overcome. Installation is easier and a desired viewing angle for users can be attained. Operation of the sunroof is not affected. As the portable display device can be attached to and removed from the sunroof, pilferage can also be prevented.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of the invention.

FIG. 2 is a perspective view of the invention.

FIG. 3 is an exploded view of the anchor mechanism of the invention.

FIG. 4 is a sectional view of the wedging mechanism of the invention.

FIG. 5 is a sectional view of the anchor mechanism of the invention.

FIG. 6 is another sectional view of the anchor mechanism of the invention.

FIG. 7 is a sectional view of the invention in an assembled condition.

FIG. 8 is another sectional view of the invention in an assembled condition.

FIG. 9 is a schematic view of the anchor mechanism of the invention in an operating condition.

### DESCRIPTION OF THE PREFERRED EMBODIMENT

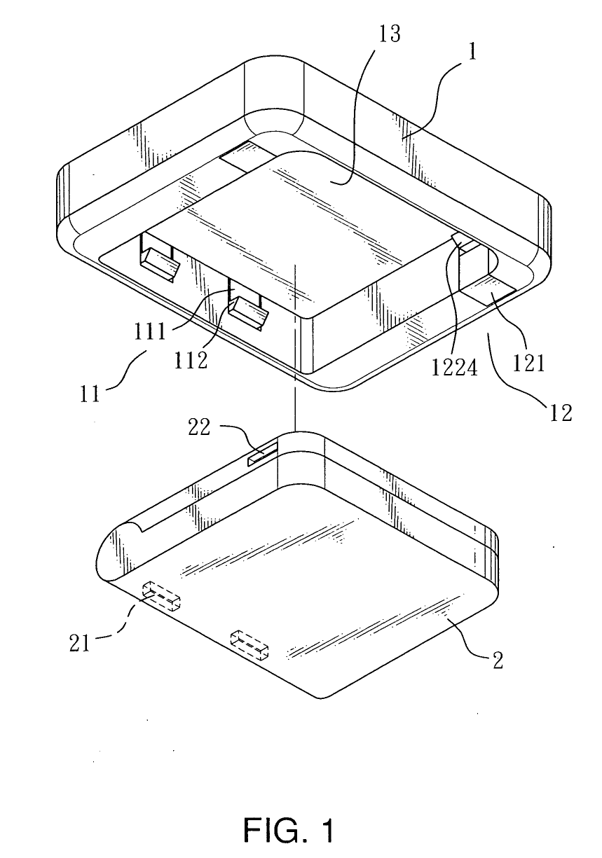

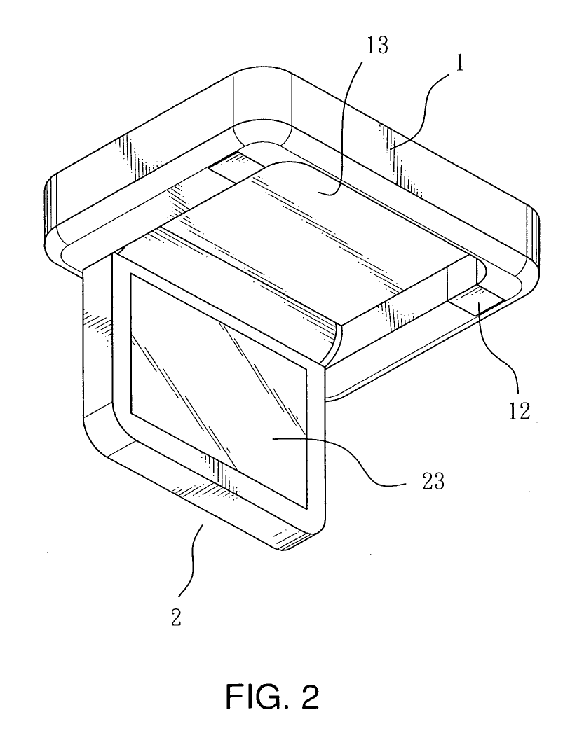

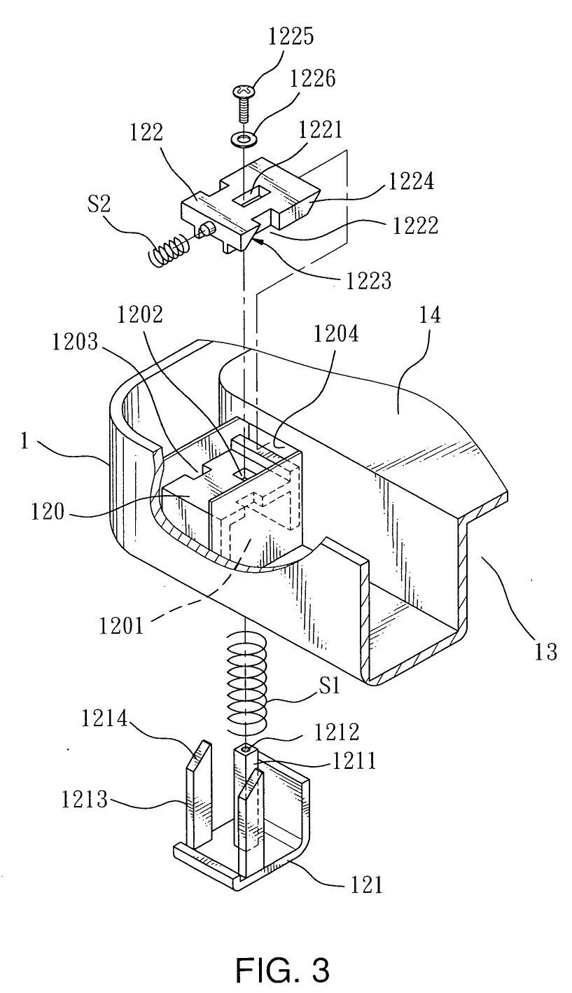

Referring to FIGS. 1, 2 and 3, the invention includes an anchor base 1 and a portable display device 2.

The anchor base 1 has a bonding surface 14 to be bonded to the bottom side of a sunroof of a vehicle. The anchor base 1 includes a housing recess 13 to hold the portable display device 2. The holding recess 13 has a wedging mechanism 11 on an inner edge and at least one anchor mechanism 12 on a lateral side.

The wedging mechanism 11 has two elastic reeds 111 each has a hook 112 on a tail end that is extended outside the inner edge of the housing recess 13.

The anchor mechanism 12 is located on a depressing dock 120, and includes a pushbutton 121 and a push element 122.

The depressing dock 120 is located on two lateral sides of the front end of the housing recess 13, and has a cavity 1201, an aperture 1202 and a first notch 1203 on each of two lateral sides. The depressing dock 120 also has a slot 1204 running through the housing recess 13.

The pushbutton 121 is held in the cavity 1201 of the depressing dock 120, and has a fastening strut 1211 which runs through a first spring S1 and the aperture 1202, and has a screw hole 1212 on the top surface. The pushbutton further has two push rods 1213 on two sides to run through the first notches 1203. Each of the push rods 1213 has sloped surface 1214 on the top side.

The push element 122 is located on a upper side of the depressing dock 120, and has an anchor hole 1221 to receive the fastening strut 1211 which is engaged with a screw 1225 and a washer 1226 for fastening. It also has two second notches 1222 on two lateral sides each has a chamfered surface 1223 mating the sloped surface 1214 of the push rod 1213. The push element 122 further has a latch tongue 1224 on a front end to be pushed by a second spring S2 so that it runs through the slot 1204 and is extended into the housing recess 13 in normal conditions.

The portable display device 2 may be held in the housing recess 13 and has a latch trough 21 on one end corresponding to the hook 112 for anchoring, and two anchor troughs 22 on two lateral sides of the front end to engage with the latch tongues 1224 of the anchor mechanism 12 so that the portable display device 2 may be held and anchored. The portable display device 2 has a display panel 23 which can be swiveled up and down to provide an optimum viewing angle for users.

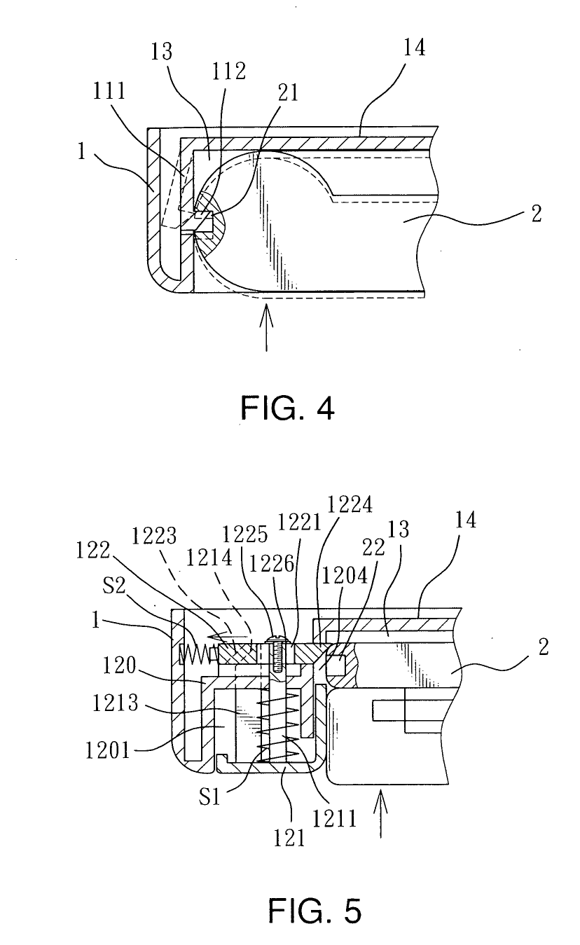

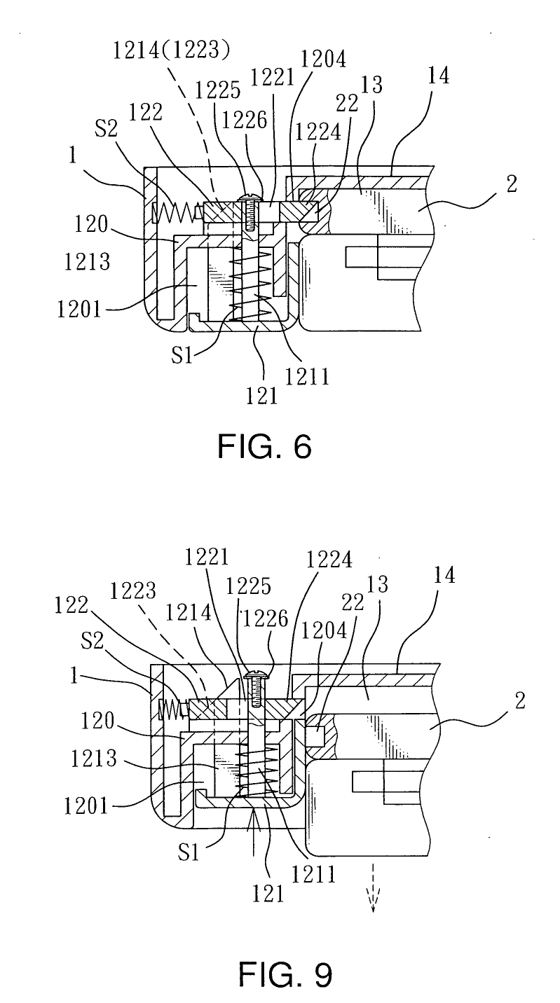

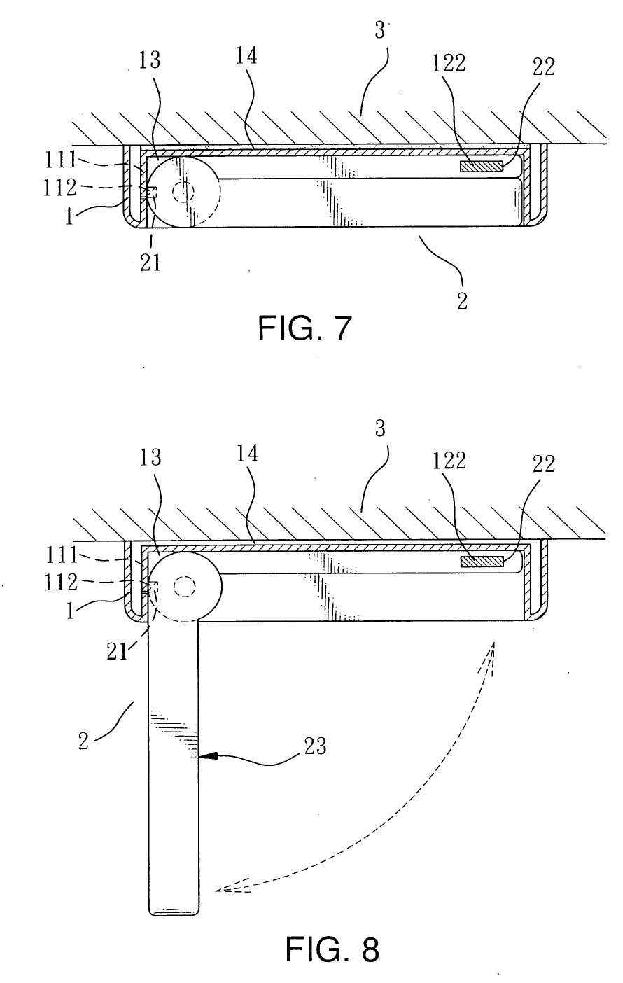

By means of the construction set forth above, for installation, first bond the bonding surface 14 of the anchor base 1 to the bottom surface of a sunroof 3 of a vehicle; wedge the portable display device 2 in the housing recess 13, with the elastic reed 111 of the wedging mechanism 11 squeezed and moved rearwards by the outer edge of the portable display device 2 so that the portable display device 2 can be fully contained in the housing recess 13; the latch trough 21 is engaged with the hook 112 of the elastic reed 111 to form an anchor condition (referring to FIG. 4); the anchor mechanism 12 on the two lateral sides of other end has the latch tongue 1224 pushed by the outer edge of the portable display device 2 so that the second spring S2 on the rear side of the push element 122 is compressed and moved rearwards; after the portable display device 2 is fully held in the housing recess 13, the anchor trough 22 is coupled with the latch tongue 1224 to form an anchoring condition (referring to FIGS. 5 and 6). Then the portable display device 2 is held firmly on the anchor base 1 (referring to FIG. 7). When in use for seeing programs, flip the display panel 23 of the portable display device 2 downwards to the optimum viewing angle (referring to FIG. 8).

When there is a desire to remove the portable display device 2 to open the sunroof or leave the vehicle, depress the pushbutton 121, the sloped surface 1214 on the top end of the push rod 1213 moves upwards to push the chamfered surface 1223 of the push element 122 so that the push element 122 is pushed rearwards; the latch tongue 1224 is retracted in the slot 1204 and disengages with the anchor trough 22; then the portable display device 2 can be removed. Release the pushbutton 121, the returning elastic forces of the springs S1 and S2 move the push element 122 forwards to the original position for installation of the next time.

In summary, the invention can be installed rapidly on the roof of vehicles that have a sunroof without affecting operation of the sunroof, and also provide an optimum viewing position for users. The portable display device can be removed easily to prevent pilferage. It offers a significant improvement over the conventional techniques.

I claim:

1. A multimedia display device attached to a sunroof of vehicles, comprising an anchor base and a portable display device; wherein:
the anchor base has a bonding surface to be bonded to the bottom surface of the sunroof and a housing recess for holding the portable display device, and at least one anchor mechanism on a lateral side;
the portable display device is anchored in the housing recess and has a display panel swivelable up and down.

2. The multimedia display device of claim 1, wherein the housing recess further has a wedging mechanism on an inner edge to anchor the portable display device.

3. The multimedia display device of claim 2, wherein the wedging mechanism has two elastic reeds each having a latch hook on a tail end to extend outside the inner edge of the housing recess.

4. The multimedia display device of claim 1, wherein the portable display device has a latch trough on one end.

5. The multimedia display device of claim 1, wherein the portable display device has an anchor trough on each of two lateral sides of a front end thereof.

6. The multimedia display device of claim 1, wherein the anchor mechanism includes a depressing dock, a pushbutton and a push element.

7. The multimedia display device of claim 6, wherein the depressing dock is located on two lateral sides of a front end of the housing recess, and has a cavity, an aperture and two first notches on two sides, and a slot running through the housing recess.

8. The multimedia display device of claim 6, wherein the pushbutton is held in the depressing dock and has a fastening strut to run through a first spring, and two push rods on two sides, each of the push rods having a sloped surface on a top side.

9. The multimedia display device of claim 6, wherein the push element is coupled on a upper side of the depressing dock, and has an anchor hole, two second notches on two lateral sides each having a chamfered surface.

10. The multimedia display device of claim 9, wherein the push element has a latch tongue on a front end to be pushed by a second spring.
